(19) United States
(12) Patent Application Publication
(10) Pub. No.: US 2025/0171261 A1
(43) Pub. Date: May 29, 2025

(54) SETUP SYSTEM AND SETUP METHOD

(71) Applicant: FUJI CORPORATION, Chiryu (JP)

(72) Inventor: Mizuho NOZAWA, Kota-cho (JP)

(73) Assignee: FUJI CORPORATION, Chiryu (JP)

(21) Appl. No.: 18/839,764

(22) PCT Filed: Mar. 31, 2022
(86) PCT No.: PCT/JP2022/016834

§ 371 Date: Aug. 20, 2024

(51) Int. Cl. B65H 19/10; B65H 19/12

(52) U.S. Cl. CPC B65H 19/105; B65H 19/12

(57) ABSTRACT

A setup system includes a storage section, a setup device, and a change section. The storage section stores at least one of component container information that is information related to a component container configured to accommodate a component to be mounted on a board and component supply unit information that is information related to a component supply unit configured to supply the component accommodated in the component container to a collection position. The setup device sets the component container to the component supply unit so that the component can be supplied from the component supply unit. The change section changes an operation condition when the setup device sets the component container to the component supply unit based on at least one of the component container information and the component supply unit information stored in the storage section.

### TECHNICAL FIELD

The present description discloses a technique related to a setup system and a setup method.

### BACKGROUND ART

A reel setting device described in Patent Literature 1 automatically performs at least a part of a work of setting a reel to a feeder. Specifically, the reel setting device accommodates the reel mounted on a cassette in accordance with an accommodation section formed in a main body portion of the feeder. For accommodating the reel, for example, an actuator including a grip section is used. Further, the reel setting device collates identification information of the reel set to the feeder and the feeder.

### PATENT LITERATURE

Patent Literature 1: International Publication No. 2019/142336

### SUMMARY OF THE INVENTION

### Technical Problem

However, in the reel setting device described in Patent Literature 1, an operation condition of the reel setting device when the reel is set to the feeder is not considered. In order to appropriately set a component container such as a reel to a component supply unit such as a feeder using a setup device, it is sometimes necessary to change an operation condition of the setup device in accordance with the component container. In some cases, it is necessary to change the operation condition of the setup device in accordance with the component supply unit. Further, it may be necessary to change the operation condition of the setup device in accordance with both the component container and the component supply unit.

In view of such circumstances, the present description discloses a setup system and a setup method capable of changing an operation condition when a setup device sets a component container to a component supply unit.

### Solution to Problem

The present description discloses a setup system including a storage section, a setup device, and a change section. The storage section stores at least one of component container information that is information related to a component container configured to accommodate a component to be mounted on a board and component supply unit information that is information related to a component supply unit configured to supply the component accommodated in the component container to a collection position. The setup device sets the component container to the component supply unit so that the component is capable of being supplied from the component supply unit. The change section changes an operation condition when the setup device sets the component container to the component supply unit based on at least one of the component container information and the component supply unit information stored in the storage section.

The present description discloses a setup method including a storage step and a change step. In the storage step, at least one of component container information that is information related to a component container configured to accommodate a component to be mounted on a board and component supply unit information that is information related to a component supply unit configured to supply the component accommodated in the component container to a collection position is stored in a storage section. In the change step, based on at least one of the component container information and the component supply unit information stored in the storage section, an operation condition is changed when a setup device configured to set the component container in the component supply unit so that the component is capable of being supplied from the component supply unit sets the component container to the component supply unit.

### Advantageous Effect of the Invention

With the above-described setup system, it is possible to change the operation condition when the setup device sets the component container to the component supply unit based on at least one of the component container information and the component supply unit information stored in the storage section. The above description of the setup system can be similarly applied to the setup method.

### BRIEF DESCRIPTION OF DRAWINGS

FIG. 1 is a perspective view illustrating an example of a setup device.

FIG. 2 is a plan view of the setup device of FIG. 1.

FIG. 3 is a perspective view illustrating an example of a feeder provided in a feeder holding section.

FIG. 4 is a plan view illustrating an example of a carrier tape.

FIG. 5 is a cross-sectional view of the carrier tape in FIG. 4.

FIG. 6 is a flowchart illustrating an example of a control procedure by the setup device.

FIG. 7 is a configuration diagram illustrating an example of a setup system.

FIG. 8 is a flowchart illustrating an example of the control procedure by the setup system.

FIG. 9 is a cross-sectional view illustrating an example of a positional relationship between the carrier tape in FIG. 4 from which a cover tape is peeled off and an imaging device or a measurement device.

### DESCRIPTION OF EMBODIMENTS

### 1. Embodiment

### 1-1. Configuration Example of Setup Device 10

Setup device 10 sets component container 92 such as reel 70 to component supply unit 93 so that component 91 can be supplied from component supply unit 93 such as feeder 60. Setup device 10 need only be capable of setting component container 92 to component supply unit 93 and may have various forms.

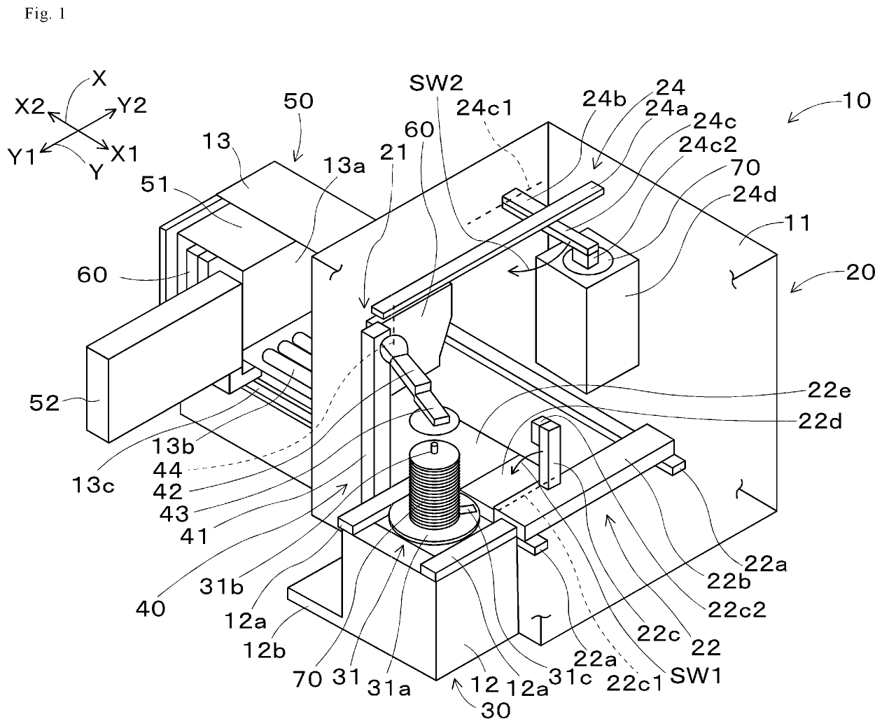

As illustrated in FIGS. 1 to 3, setup device 10 of an embodiment includes reel attachment/detachment section 20, reel supply section 30, reel transfer mechanism 40, and feeder supply section 50. Note that, for convenience of description, in the drawings, a facing direction of feeder 60 and reel 70 when reel 70 is attached to and detached from feeder 60 is referred to as a first direction (arrow X direction). In the first direction (arrow X direction), a direction (side) from feeder 60 toward reel 70 is referred to as a first end side (arrow X1 direction) in the first direction, and a direction (side) from reel 70 toward feeder 60 is referred to as a second end side (arrow X2 direction) in the first direction.

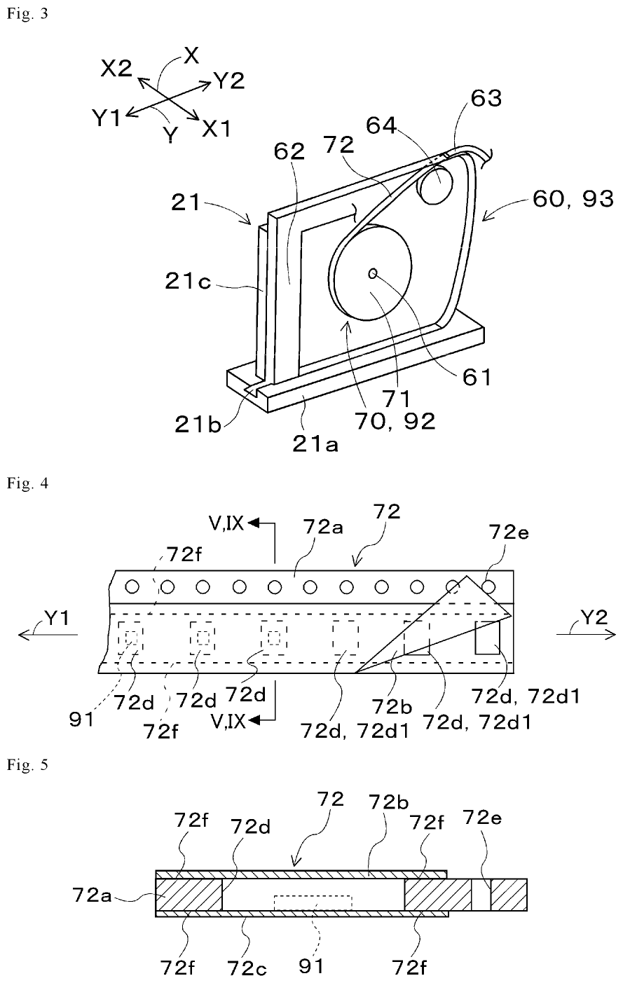

Further, as illustrated in FIG. 3, a sliding direction of feeder 60 in slot 21b, which is a direction orthogonal to the first direction (arrow X direction) in a horizontal plane, is referred to as a second direction (arrow Y direction). In the second direction (arrow Y direction), a sliding direction (side) when feeder 60 is detached is referred to as a first end side (arrow Y1 direction) in the second direction, and a sliding direction (side) when feeder 60 is attached is referred to as a second end side (arrow Y2 direction) in the second direction.

In reel attachment/detachment section 20, various members are assembled inside first housing 11. First housing 11 is a case having a rectangular parallelepiped shape, and a second end side (arrow X2 direction) in the first direction thereof and a first end side (arrow Y1 direction) in the second direction thereof are partially opened. Reel supply section 30 is provided to be coupled to a first end side (arrow Y1 direction) in the second direction of reel attachment/detachment section 20. Reel supply section 30 is formed in box-shaped base 12 smaller than first housing 11. Reel transfer mechanism 40 is provided on plate seat 12b extending from a bottom portion of base 12 to a second end side (arrow X2 direction) in the first direction. Feeder supply section 50 is provided to be coupled to a second end side (arrow X2 direction) in the first direction of reel attachment/detachment section 20. In feeder supply section 50, various members are assembled inside second housing 13 which is smaller than first housing 11 and has storage space 13a in an upper portion.

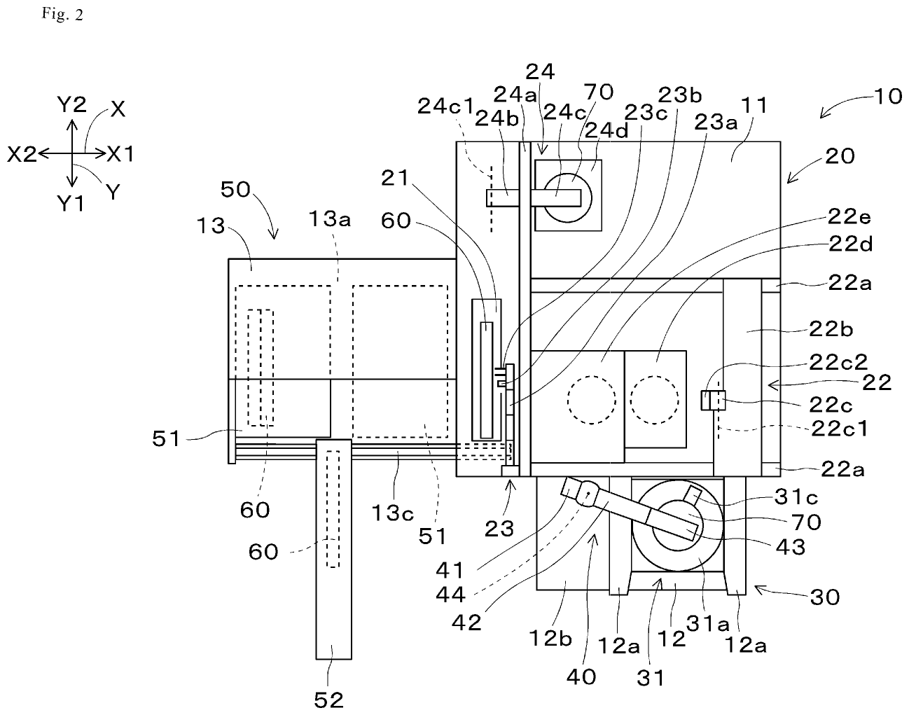

Reel attachment/detachment section 20 includes feeder holding section 21, reel attachment mechanism 22, tape loading mechanism 23, and reel detachment mechanism 24. As illustrated in FIG. 2, feeder holding section 21 is disposed on the second end side (arrow X2 direction) in the first direction and first end side (arrow Y1 direction) in the second direction inside first housing 11. Feeder holding section 21 holds feeder 60 at a work execution position in a vertical posture. As illustrated in FIG. 3, feeder holding section 21 includes bottom plate 21a, slot 21b, and support plate 21c. Slot 21b is formed in a groove shape extending along the second direction (arrow Y direction) in bottom plate 21a. Feeder 60 is inserted from a first end side (arrow Y1 direction) in the second direction of slot 21b toward the second end side (arrow Y2 direction) in the second direction, and is held at the work execution position. Support plate 21c is provided to stand up from bottom plate 21a, and comes into contact with the side surface of feeder 60 at the work execution position on the second end side (arrow X2 direction) in the first direction. Support plate 21c supports a pressing load to the second end side (arrow X2 direction) in the first direction generated when reel 70 is attached to feeder 60.

Feeder 60 is detachably mounted on a component mounter. As illustrated in FIG. 3, in feeder 60, reel 70 around which carrier tape 72 is wound is attached to main body portion 71, and carrier tape 72 is conveyed to supply component 91. An identification code for identifying reel 70 is given to each reel 70. Feeder 60 is formed in a flat box shape. Feeder 60 includes reel holding shaft 61 that protrudes from a side plate at the second end side (arrow X2 direction) in the first direction toward the first end side (arrow X1 direction) in the first direction at a substantially central position as viewed in the first direction (arrow X direction). Reel holding shaft 61 is inserted into a center hole formed at the center of reel 70, and detachably and rotatably holds reel 70

As illustrated in FIGS. 4 and 5, carrier tape 72 includes base tape 72a, cover tape 72b, and bottom tape 72c. Base tape 72a is a base portion of carrier tape 72, and is provided with multiple accommodation sections 72d and multiple feed holes 72e. Component 91 is accommodated in each of multiple accommodation sections 72d. As illustrated in FIG. 4, a predetermined number (for example, three in FIG. 4) of accommodation sections 72d from the distal end side of carrier tape 72 are empty accommodation sections 72d1 in which components 91 are not accommodated. Multiple accommodation sections 72d are provided at predetermined pitch intervals in the longitudinal direction of carrier tape 72 at the center portion in the width direction of base tape 72a.

Each of multiple feed holes 72e is a through hole, and is used when carrier tape 72 is conveyed in the conveyance direction (the second end side (arrow Y2 direction) in the second direction). Multiple feed holes 72e are provided at a predetermined pitch interval in the longitudinal direction of carrier tape 72 on a first end side in the width direction of base tape 72a. Cover tape 72b closes accommodation section 72d of base tape 72a. Cover tape 72b is attached to the upper surfaces of both end portions of base tape 72a in the width direction by, for example, adhesive 72f or thermocompression bonding. Bottom tape 72c is attached to the lower surface of base tape 72a by, for example, adhesive 72f or thermocompression bonding, and prevents component 91 accommodated in accommodation section 72d from falling off.

A central portion of side plate 62 on a first end side (arrow X1 direction) in the first direction of feeder 60 is open in order to facilitate attachment and detachment of reel 70. At least one of the material of carrier tape 72, the width dimension of carrier tape 72, the width dimension of reel 70, and the diameter dimension of reel 70 is different among multiple types of reels 70, and there are multiple types of feeders 60 corresponding to multiple types of reels 70. Feeder 60 includes collection position 63, sprocket 64, and a tape peeling section.

Collection position 63 is provided on a second end side (arrow Y2 direction) in the second direction of the upper surface of feeder 60, and the component mounter collects component 91 at collection position 63. Sprocket 64 is rotatably provided on a first end side (arrow Y1 direction) in the second direction from collection position 63. A teeth portion of sprocket 64 engage with feed holes 72e of carrier tape 72. Sprocket 64 is intermittently driven by a drive motor and conveys carrier tape 72 at a constant pitch. The tape peeling section can peel off cover tape 72b from base tape 72a immediately before collection position 63 to take out component 91. After passing through collection position 63, carrier tape 72 is cut by a tape cutting device provided in the component mounter.

It should be noted that an identification code for identifying feeder 60 is given to each of feeders 60. Feeder 60 is provided with a feeder control section. The feeder control section stores the identification code of feeder 60 and the identification code of reel 70, and controls the component supply operation. When feeder 60 is held by feeder holding section 21, the connectors are fitted to each other, and the feeder control section is communicably connected to setup device 10.

Reel attachment mechanism 22 is provided on a first end side (arrow X1 direction) in the first direction of feeder holding section 21. Reel attachment mechanism 22 uses reel transfer mechanism 40 to change reel 70 in a horizontal posture to a vertical posture and attach reel 70 to feeder 60 at the work execution position. Reel attachment mechanism 22 includes pair of guide rails 22a and 22a, moving table 22b, attachment material 22c, placement area 22d, and temporary placement area 22e. Note that, in reel attachment mechanism 22, a mechanism that changes reel 70 in the horizontal posture to the vertical posture and a mechanism that attaches reel 70 in the vertical posture to feeder 60 may be separated.

Pair of guide rails 22a and 22a extends along the first direction (arrow X direction) at a substantially central position in the second direction (arrow Y direction) of first housing 11, and is disposed in parallel to be separated from each other. Moving table 22b extends along the second direction (arrow Y direction), and is provided to straddle the upper side of pair of guide rails 22a and 22a. As illustrated in FIGS. 1 and 2, moving table 22b moves along pair of guide rails 22a and 22a, and reciprocates between a standby position provided on the first end side (arrow X1 direction) in the first direction and feeder holding section 21 provided on the second end side (arrow X2 direction) in the first direction.

Attachment material 22c is formed in a square bar shape, and is provided to extend upward from moving table 22b. Attachment material 22c faces reel holding shaft 61 of feeder 60 at the work execution position. Specifically, attachment material 22c is provided at a position separated by a predetermined distance from a distal end portion of reel holding shaft 61 toward the first end side (arrow X1 direction) in the first direction. Attachment material 22c swings (arrow SW1 in FIG. 1) between an upright posture illustrated in FIGS. 1 and 2 and a horizontal posture in which attachment material 22c is tilted toward the second end side (arrow X2 direction) in the first direction around swing shaft 22c1 provided on moving table 22b side. Collection section 22c2 is provided on an end portion different from an end portion of swing shaft 22c1 side of attachment material 22c. Collection section 22c2 detachably collects reel 70. As collection section 22c2, a claw portion inserted into the center hole of reel 70, a gripping mechanism that grips a peripheral edge of reel 70, a pickup mechanism that picks up reel 70 using negative pressure, or the like can be used.

Placement area 22d is provided on the first end side (arrow X1 direction) in the first direction in pair of guide rails 22a and 22a. In placement area 22d, reel 70 to be attached is placed in a horizontal posture. Temporary placement area 22e is provided on pair of guide rails 22a and 22a on the second end side (arrow X2 direction) in the first direction with respect to placement area 22d. In temporary placement area 22e, when reel attachment mechanism 22 changes the use order of reels 70, reels 70 are temporarily placed in the horizontal posture and the use order of reels 70 is changed. In temporary placement area 22e, an area in which multiple reels 70 can be temporarily placed is secured. Moving table 22b and attachment material 22c move above placement area 22d and temporary placement area 22e.

As illustrated in FIG. 2, tape loading mechanism 23 is provided near feeder holding section 21. Tape loading mechanism 23 loads carrier tape 72 in feeder 60 so that carrier tape 72 can be fed. For example, an articulated robot can be used as tape loading mechanism 23. Tape loading mechanism 23 of the embodiment includes articulated arm 23a, camera 23b, and multiple fingers 23c.

Articulated arm 23a can perform operations such as rotation and bending of the arm, and can adjust the positions and directions of camera 23b and multiple fingers 23c. Camera 23b is provided at the distal end portion of articulated arm 23a. Camera 23b images feeder 60 at the work execution position to detect the positions and the states of reel 70 and carrier tape 72. Multiple fingers 23c are provided side by side with camera 23b at the distal end portion of articulated arm 23a. Multiple fingers 23c can perform a moving operation, a twisting operation, and the like in addition to the operation of gripping and releasing a work target.

Multiple fingers 23c load carrier tape 72 so that feed hole 72e at the distal end portion of carrier tape 72 engages with sprocket 64, and set carrier tape 72 in a feedable state. Multiple fingers 23c facilitate the loading operation of carrier tape 72 by rotating reel 70 around reel holding shaft 61 as necessary. Tape loading mechanism 23 takes a retracted posture in which articulated arm 23a is bent not to hinder the attaching and detaching operation of reel 70 in a time period other than the operation time.

Reel detachment mechanism 24 is provided on a first end side (arrow X1 direction) in the first direction of feeder holding section 21, and is disposed above reel attachment mechanism 22. Reel detachment mechanism 24 detaches reel 70 from feeder 60 at the work execution position. Reel detachment mechanism 24 includes guide rail 24a, moving table 24b, detachment material 24c, and collection box 24d.

Guide rail 24a is provided in the vicinity of the ceiling of first housing 11, and is formed to extend along the second direction (arrow Y direction). Moving table 24b is formed to extend along the first direction (arrow X direction), and is provided below guide rail 24a. As illustrated in FIGS. 1 and 2, moving table 24b moves along guide rail 24a and reciprocates between feeder holding section 21 and a standby position provided on the second end side (arrow Y2 direction) in the second direction.

Detachment material 24c is formed of a thick plate-shaped member longer than moving table 24b, and is provided to extend along the first direction (arrow X direction) below moving table 24b. Detachment material 24c swings (arrow SW2 in FIG. 1) between a horizontal posture illustrated in FIGS. 1 and 2 and a vertical posture in which detachment material 24c is tilted downward around swing shaft 24c1 provided on a second end side (arrow X2 direction) in the first direction of moving table 24b. Collection section 24c2 is provided on an end portion on a side different from the end portion on swing shaft 24c1 side of detachment material 24c. Collection section 24c2 detachably collects reel 70. The collecting method by collection section 24c2 may be the same as or different from collection section 22c2 of reel attachment mechanism 22.

Collection box 24d is provided to be positioned below detachment material 24c when moving table 24b is moved to the standby position. Collection box 24d collects multiple detached reels 70. Collection box 24d is formed in a box shape opening upward. Accordingly, collection box 24d can collect falling reel 70 by collection section 24c2 of detachment material 24c releasing reel 70.

Reel supply section 30 includes reel holding section 31 that is detachably provided. Pair of guide plates 12a and 12a extending along the second direction (arrow Y direction) is provided on a first end side (arrow X1 direction) in the first direction and second end side (arrow X2 direction) in the first direction of the upper surface of base 12. Reel holding section 31 is placed between pair of guide plates 12a and 12a of base 12. As illustrated in FIG. 2, surfaces of pair of guide plates 12a and 12a facing each other on the first end side (arrow Y1 direction) in the second direction are formed in a tapered shape, and a separation distance on the first end side (arrow Y1 direction) in the second direction is longer than that on the second end side (arrow Y2 direction) in the second direction. This facilitates the work of inserting reel holding section 31 toward base 12 from the first end side (arrow Y1 direction) in the second direction.

Reel holding section 31 stacks and holds multiple reels 70 in a horizontal posture. Note that reel 70 is not limited to an unused reel, and may be a reel in use in which carrier tape 72 has been used halfway. Reel holding section 31 includes a circular plate-shaped holding plate 31a provided horizontally, and round rod-shaped holding shaft 31b provided upward from the center of holding plate 31a and penetrating through the center hole of reel 70. Accordingly, reel holding section 31 can hold multiple reels 70 in a state where holding shaft 31b penetrates through the center holes of multiple reels 70 even when reels 70 having at least one of different diameter dimension and different width dimension are mixed, and reel 70 can be easily taken out. Identification code 31c is given to an upper surface of holding plate 31a. Identification code 31c includes information for specifying reel holding section 31.

For example, a worker procures multiple reels 70 based on work instruction data, and performs a stacking work of stacking multiple reels 70 on reel holding section 31. The work instruction data indicates a work content of the setup work performed by setup device 10. That is, in the work instruction data, the type information of multiple reels 70 required with the progress of the production of the board product by the component mounter is associated with the type information of multiple feeders 60 applicable to reels 70. Note that a known automated guided vehicle or the like may be used to convey multiple reels 70.

Reel transfer mechanism 40 is provided on plate seat 12b extending from a bottom portion of base 12 to a second end side (arrow X2 direction) in the first direction. Reel transfer mechanism 40 includes support column 41, arm 42, and collection section 43. Support column 41 stands upward in the vertical direction on a second end side (arrow Y2 direction) in the second direction of plate seat 12b. Arm 42 is provided to be capable of being lifted and lowered with respect to support column 41. Further, arm 42 is provided to be rotatable on a horizontal plane around rotation axis 44 close to support column 41.

Collection section 43 is provided to be extendable and contractible with respect to arm 42. Collection section 43 detachably collects reel 70. The collecting method by collection section 43 may be the same as or different from collection section 22c2 of reel attachment mechanism 22 and collection section 24c2 of reel detachment mechanism 24. Collection section 43 is provided with a code reader. The code reader reads identification code 31c of reel holding section 31. Further, the code reader can read the identification code of uppermost reel 70.

Reel transfer mechanism 40 functions as a part of reel attachment mechanism 22. Specifically, reel transfer mechanism 40 takes out reel 70 from reel holding section 31 by driving arm 42 and collection section 43. Further, reel transfer mechanism 40 places taken out reel 70 in placement area 22d or temporary placement area 22e in the state of the horizontal posture by driving arm 42 and collection section 43. Reel transfer mechanism 40 subsequently uses multiple reels 70 stacked on reel holding section 31 from the uppermost portion.

Feeder supply section 50 includes feeder accommodation section 51 that is detachably provided and feeder conveyance section 52. As illustrated in FIG. 2, storage space 13a in the upper portion of second housing 13 is open on the first end side (arrow Y1 direction) in the second direction, and can store multiple (for example, two in FIG. 2) feeder accommodation sections 51 arranged along the first direction (arrow X direction). As illustrated in FIG. 1, multiple roller conveyors 13b extending along the first direction (arrow X direction) are provided on a bottom surface defining storage space 13a, so that a storage operation of feeder accommodation section 51 is facilitated.

Feeder accommodation section 51 is formed in a box shape whose first end side (arrow Y1 direction) in the second direction is opened. Multiple slots having the same shape as slot 21b of feeder holding section 21 are formed on the bottom surface of feeder accommodation section 51. Feeder accommodation section 51 can accommodate multiple feeders 60 in a vertical posture arranged along a first direction (arrow X direction). When multiple feeders 60 are accommodated in feeder accommodation section 51 and feeder accommodation section 51 is properly stored in storage space 13a, the connectors of feeder 60 and feeder accommodation section 51 are fitted to each other, and multiple feeder control sections are communicably connected to setup device 10.

An identification code for identifying feeder accommodation section 51 is given to feeder accommodation section 51. For example, the worker procures multiple feeders 60 to be used based on the work instruction data, and performs the accommodation work of accommodating feeders 60 in feeder accommodation section 51. The number of feeder accommodation sections 51 that can be accommodated in storage space 13a may be one or three or more. A known automated guided vehicle or the like can also be used for conveying multiple feeders 60.

Guide rail 13c is provided in a lower portion on a first end side (arrow Y1 direction) in the second direction of storage space 13a of second housing 13. Guide rail 13c is provided in storage space 13a over substantially the entire first direction (arrow X direction), and is provided to extend to a first end side (arrow Y1 direction) in the second direction of feeder holding section 21. Guide rail 13c is provided with feeder conveyance section 52. Feeder conveyance section 52 moves along guide rail 13c and reciprocates between feeder accommodation section 51 and feeder holding section 21.

Feeder conveyance section 52 is formed in a box shape having an opening portion on the second end side (arrow Y2 direction) in the second direction. Feeder conveyance section 52 includes a built-in space that temporarily incorporates feeder 60, and a feeder operation mechanism that carries feeder 60 into built-in space through the opening portion and carries feeder 60 out of built-in space. Accordingly, feeder conveyance section 52 can carry feeder 60 out of feeder accommodation section 51 and feeder holding section 21, and can carry feeder 60 into feeder accommodation section 51 and feeder holding section 21. An openable and closable safety fence is provided on a first end side (arrow Y1 direction) in the second direction of reel supply section 30 and feeder supply section 50, and the approach of the worker to reel supply section 30 and feeder supply section 50 is suppressed.

### 1-2. Control Example of Setup Device 10

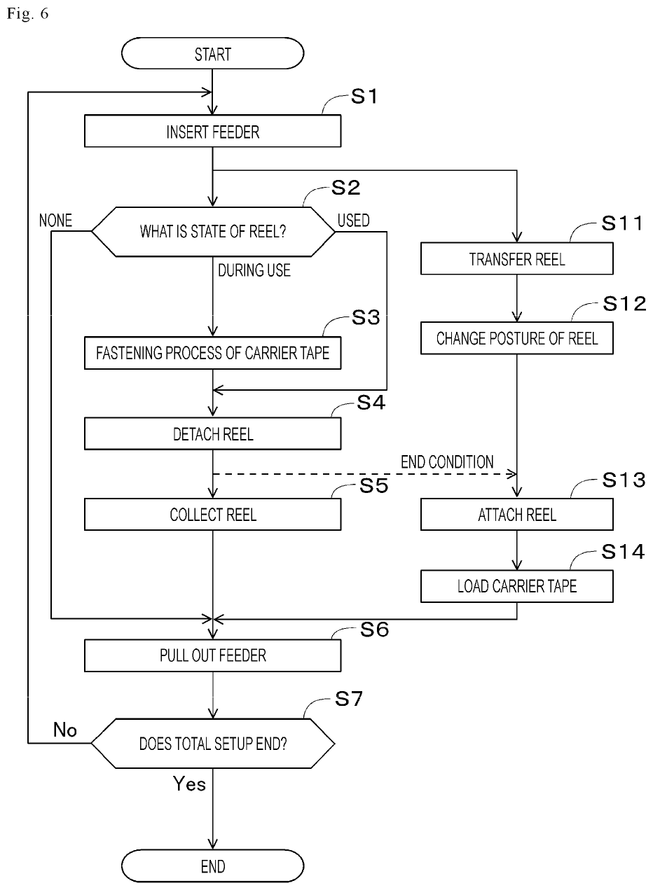

Setup device 10 causes feeder conveyance section 52 to convey feeder 60 corresponding to uppermost reel 70 of reel holding section 31 (Step S1 illustrated in FIG. 6). Feeder conveyance section 52 pulls out and incorporates feeder 60 from feeder accommodation section 51, moves to feeder holding section 21, and inserts incorporated feeder 60 into feeder holding section 21. Accordingly, feeder 60 is held at the work execution position, and the identification code of feeder 60 is read.

When there is no feeder 60 applicable to uppermost reel 70 of reel holding section 31, reel 70 is placed in temporary placement area 22e by reel transfer mechanism 40. The above-described placement is repeated until applicable feeder 60 is present, and feeder 60 corresponding to uppermost reel 70 of reel holding section 31 is inserted into feeder holding section 21. After the control illustrated in Step S1, in setup device 10, a first-series control illustrated in Steps S2 to S5 and a second-series control illustrated in Steps S11 to S14 are executed in parallel.

In the first-series control, setup device 10 checks the state of reel 70 based on the read identification code of feeder 60 or the read identification code of reel 70, and changes the control according to the state of reel 70 (Step S2). Specifically, in a case where feeder 60 is used in the component mounter in advance, there is a possibility that reel 70 in use in which carrier tape 72 is used halfway is provided in feeder 60. In this case, tape loading mechanism 23 performs a fastening process of fixing the distal end portion of carrier tape 72 with a tape or the like to suppress slack of carrier tape 72 (Step S3). At this time, tape loading mechanism 23 can wind carrier tape 72 around reel 70 as necessary. Thereafter, tape loading mechanism 23 takes a retracted posture in which articulated arm 23a is bent.

Next, reel detachment mechanism 24 detaches reel 70 from feeder 60 (Step S4). Specifically, moving table 24b moves from the standby position to feeder holding section 21. Then, when detachment material 24c is swung from the horizontal posture to the vertical posture, collection section 24c2 abuts on reel 70 and collects reel 70. Then, when detachment material 24c returns from the vertical posture to the horizontal posture, collection section 24c2 pulls out reel 70 from reel holding shaft 61 and holds reel 70 in the horizontal posture. At this time, setup device 10 deletes the identification code of reel 70 from the storage section of the feeder control section of feeder 60. Further, setup device 10 transmits the identification code of feeder 60 from which reel 70 has been detached to a higher-level management device. At this time, setup device 10 may transmit the identification code of detached reel 70 together with the identification code of feeder 60 to the higher-level management device.

Next, reel detachment mechanism 24 collects reel 70 (Step S5). Specifically, first, moving table 24b moves from feeder holding section 21 to the standby position. Then, collection section 24c2 releases reel 70. Thus, released reel 70 falls into collection box 24d and is collected. When reel 70 is collected, the first-series control is in a standby state until the second-series control ends.

Note that there is a possibility that feeder 60 is equipped with used reel 70 in which all the carrier tapes 72 have been used (Step S2). In this case, in the first-series control, the control illustrated in Step S3 is omitted, and the controls illustrated in Step S4 and Step S5 are executed. There is a possibility that feeder 60 is not equipped with reel 70 (Step S2). In this case, in the first-series control, the control illustrated in Steps S3 to S5 is omitted.

In the second-series control, reel transfer mechanism 40 collects uppermost reel 70 of reel holding section 31 using collection section 43, and places reel 70 on placement area 22d (Step S11). Then, reel transfer mechanism 40 returns collection section 43 to above reel holding section 31. When there is no applicable feeder 60, reel transfer mechanism 40 places reel 70 in temporary placement area 22e.

Next, reel attachment mechanism 22 changes the posture of reel 70 in placement area 22d (Step S12). Specifically, first, attachment material 22c is changed from the upright posture to the horizontal posture, and collection section 22c2 abuts on reel 70 to collect reel 70. Then, attachment material 22c is returned from the horizontal posture to the upright posture, and collection section 22c2 changes reel 70 from the horizontal posture to the vertical posture and holds reel 70. When reel 70 in temporary placement area 22e is used, moving table 22b moves to the second end side (arrow X2 direction) in the first direction by a predetermined distance before attachment material 22c shifts from the upright posture to the horizontal posture. The second-series control is in a standby state until an end condition indicating the completion of the control of Step S4 of the first series is satisfied. This avoids interference between reel attachment mechanism 22 and reel detachment mechanism 24.

When the end condition is satisfied, reel attachment mechanism 22 attaches reel 70 to feeder 60 (Step S13). Specifically, in a state where collection section 22c2 holds reel 70 in the vertical posture, moving table 22b moves to feeder holding section 21. Accordingly, reel 70 moves toward reel holding shaft 61 and is attached to reel holding shaft 61. The movement of moving table 22b can be performed simultaneously with the movement of moving table 24b to the standby position.

When the attachment of reel 70 ends, setup device 10 stores the identification code of reel 70 in the feeder control section of feeder 60 to which reel 70 is attached. Further, setup device 10 transmits the identification code of feeder 60 and the identification code of reel 70 mounted on feeder 60 to the higher-level management device in association with each other. Moving table 22b returns to the standby position. Next, tape loading mechanism 23 loads carrier tape 72 until feed holes 72e of carrier tape 72 engage with the teeth portion of sprocket 64 (Step S14).

When the first-series control and the second-series control end, feeder conveyance section 52 pulls out feeder 60 from feeder holding section 21, incorporates feeder 60 therein, moves feeder 60 to feeder accommodation section 51, and inserts incorporated feeder 60 into feeder accommodation section 51 (Step S6). Thus, the setup work for one feeder 60 ends. Setup device 10 determines whether the setup work for all feeders 60 ends (Step S7). When the setup work for all feeders 60 ends (Yes in Step S7), the control by setup device 10 temporarily ends. When the setup work for all feeders 60 does not end (No in Step S7), the control by setup device 10 returns to the control illustrated in Step S1, and the control described above is repeated until the setup work for all feeders 60 ends.

When the control by setup device 10 ends, for example, the worker conveys feeder accommodation section 51 accommodating feeder 60 that has been set up to the component mounter, and performs the setup change of feeder 60. In a case where reel 70 is placed in temporary placement area 22e, when the worker accommodates feeder 60 applicable to reel 70 in feeder accommodation section 51, reel 70 becomes usable. Further, reel 70 left unused in temporary placement area 22e is returned to reel holding section 31 by reel transfer mechanism 40 and collected by the worker. Further, the above-described conveyance work by the worker can also be automated using a known automated guided vehicle or the like.

### 1-3. Configuration Example of Setup System 80

For example, when the type of reel 70 is different, the type of carrier tape 72 wound around reel 70 may be different. When the type of carrier tape 72 is different, the operation condition of tape loading mechanism 23 when loading carrier tape 72 may be different. In addition, for example, when the type of feeder 60 is different, an opening method of opening accommodation section 72d of carrier tape 72 may be different. When the opening method of accommodation section 72d is different, the operation condition of tape loading mechanism 23 when loading carrier tape 72 may be different.

As described above, in order to appropriately set component container 92 such as reel 70 to component supply unit 93 such as feeder 60 using setup device 10, it may be necessary to change the operation condition of setup device 10 in accordance with component container 92. In some cases, it may be necessary to change the operation condition of setup device 10 in accordance with component supply unit 93. Further, it may be necessary to change the operation condition of setup device 10 in accordance with both component container 92 and component supply unit 93. In the embodiment, setup system 80 is provided.

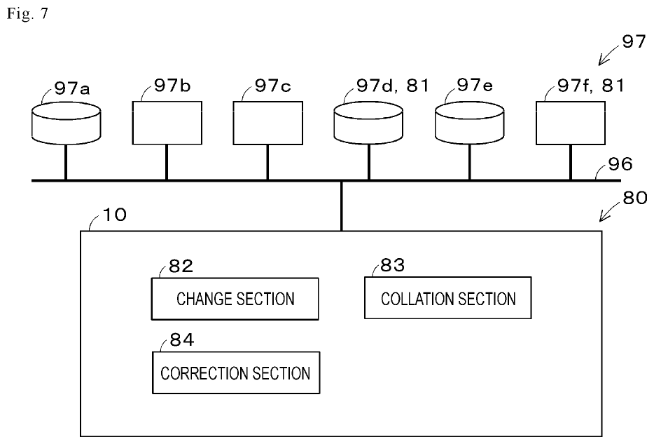

Setup system 80 includes storage section 81, setup device 10, and change section 82. Setup system 80 may include collation section 83. Setup system 80 may include correction section 84. As illustrated in FIG. 7, setup system 80 of the embodiment includes storage section 81, setup device 10, change section 82, collation section 83, and correction section 84. As described above, setup device 10 sets component container 92 to component supply unit 93 so that component 91 can be supplied from component supply unit 93. Setup device 10 need only be capable of setting component container 92 to component supply unit 93 and may have various forms as described above.

Storage section 81 stores information described later. Storage section 81 need only be capable of storing information described later and may be any known storage device, database, or the like. Change section 82, collation section 83, and correction section 84 may be provided in various arithmetic devices, control devices, and management devices. At least one of storage section 81, change section 82, collation section 83, and correction section 84 may be formed on a cloud. As illustrated in FIG. 7, in the embodiment, storage section 81 is provided in material database 97d and production management system 97f of production system 97. Change section 82, collation section 83, and correction section 84 are provided in the control device of setup device 10.

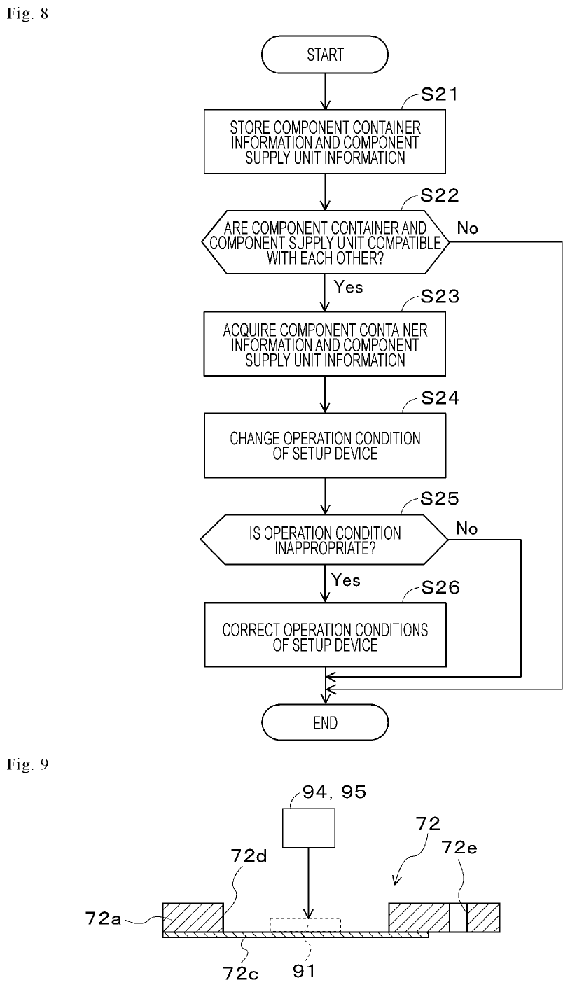

Setup system 80 of the embodiment performs control according to the flowchart illustrated in FIG. 8. Storage section 81 performs the processing illustrated in Step S21. Change section 82 performs processing illustrated in Steps S23 and S24. Collation section 83 performs determination illustrated in Step S22. Correction section 84 performs determination and processing illustrated in Steps S25 and S26.

### 1-3-1. Storage Section 81

Storage section 81 stores at least one of the component container information and the component supply unit information. The component container information is information related to component container 92 that accommodates component 91 mounted on the board, and includes various information related to component container 92. The component supply unit information is information related to component supply unit 93 that supplies component 91 accommodated in component container 92 to collection position 63, and includes various information related to component supply unit 93.

For example, component container 92 of the embodiment is reel 70. As illustrated in FIG. 3, carrier tape 72 is wound around reel 70. As illustrated in FIGS. 4 and 5, in carrier tape 72, cover tape 72b that closes accommodation section 72d is provided in base tape 72a provided with accommodation section 72d that accommodates component 91. As described later, for example, when the type of reel 70 is different and the type of carrier tape 72 is different, the operation condition of setup device 10 in the case of positioning leading accommodation section 72d accommodating component 91 at a predetermined position with respect to collection position 63 may be different.

As described above, when the types of the component containers 92 such as reel 70 and carrier tape 72 are different, the operation conditions of setup device 10 may be different. Therefore, the component container information may include information related to the type of component container 92. Even when the type of component container 92 is the same, for example, when the manufacturer of component container 92 is different, the operation condition of setup device 10 may be different. Therefore, the component container information can include information related to the manufacturer of component container 92.

Further, as will be described later, the determination method in positioning may be different depending on component 91. Therefore, the component container information may include component information which is information related to component 91 contained in component container 92. Information related to the shape of component 91 (for example, information such as the size of component 91, the presence or absence of the lead of component 91, the position of the lead, the length of the lead, and the pitch of the lead) is included in the component information. In addition, information related to the remaining number of components 91 accommodated in carrier tape 72 is included in the component information. Further, information related to the electrical characteristics (for example, a resistance value when component 91 is a resistor) of component 91 is included in the component information.

For example, component supply unit 93 of the embodiment is feeder 60. As illustrated in FIG. 3, feeder 60 conveys carrier tape 72 in a state of rotatably supporting reel 70. Then, feeder 60 opens accommodation section 72d closed by cover tape 72b on the upstream side (the first end side (arrow Y1 direction) in the second direction) of collection position 63, and supplies component 91 to collection position 63. As described later, for example, when the type of feeder 60 is different, the opening method of accommodation section 72d may be different.

As described above, when the type of component supply unit 93 such as feeder 60 is different, the operation condition of setup device 10 may be different. Therefore, the component supply unit information may include information related to the type of component supply unit 93. Even when the type of component supply unit 93 is the same, for example, when the manufacturer of component supply unit 93 is different, the operation condition of setup device 10 may be different. Therefore, the component supply unit information can also include information related to the manufacturer of component supply unit 93.

In the embodiment, storage section 81 stores both the component container information and the component supply unit information (Step S21 illustrated in FIG. 8). As illustrated in FIG. 7, storage section 81 is provided in material database 97d and production management system 97f of production system 97. FIG. 7 illustrates an example of production system 97 for producing a board product by a board work for performing a predetermined board work on a board. Production system 97 is communicably connected to various board work machines by wired or wireless communication section 96. Production system 97 is communicably connected to setup device 10 via communication section 96.

Production system 97 of the embodiment includes maintenance database 97a, higher-level system 97b, location management system 97c, material database 97d, layout management system 97e, and production management system 97f. Maintenance database 97a stores maintenance information (for example, maintenance timing, the number of times of maintenance execution, and the like) of various members to be used in production of board products. Maintenance database 97a stores, for example, maintenance information of component supply unit 93 such as feeder 60. Higher-level system 97b is a higher-level management system and manages various types of information.

Location management system 97c manages location information on the production floor of the members to be used. Location management system 97c manages, for example, location information of component container 92 and component supply unit 93. Material database 97d stores information related to a member to be used. Material database 97d stores, for example, component information, manufacturers of component container 92 and component supply unit 93, and the like. Material database 97d stores, among the component information, information related to the remaining number of components 91 accommodated in carrier tape 72, information related to the electrical characteristics of components 91, and the like. Material database 97d can store other component container information or can store component supply unit information.

Layout management system 97e stores a configuration of a production line for producing a board product, a configuration of a board work machine provided in each production line, and the like. Production management system 97f manages production of board products in the board work machine. In addition, production management system 97f stores information related to members to be used. Production management system 97f stores, for example, a mounting position of component supply unit 93 such as feeder 60 in the component mounter. Production management system 97f stores, for example, component information. Production management system 97f stores, for example, information related to the shape of component 91 among the component information. Production management system 97f can store other component container information and can also store component supply unit information. For example, production management system 97f stores at least the type of component container 92 and the type of component supply unit 93. Further, the component container information and the component supply unit information stored in storage section 81 of production management system 97f are used to control the board work machine.

### 1-3-2. Change Section 82

Change section 82 changes the operation condition when setup device 10 sets component container 92 to component supply unit 93 based on at least one of the component container information and the component supply unit information stored in storage section 81. In the embodiment, storage section 81 stores both the component container information and the component supply unit information. Change section 82 acquires both the component container information and the component supply unit information stored in storage section 81 (Step S23 illustrated in FIG. 8). Then, change section 82 changes the operation condition of setup device 10 based on the component container information and the component supply unit information (Step S24).

Change section 82 need only be capable of changing the operation conditions of setup device 10 and may have various forms. Change section 82 changes the operation condition to an operation condition that matches component container 92 and component supply unit 93 to be set by setup device 10. In the embodiment, component container 92 is reel 70 in which carrier tape 72 provided with cover tape 72b that closes accommodation section 72d is wound around base tape 72a provided with accommodation section 72d that accommodates component 91.

As illustrated in FIG. 4, a predetermined number (for example, three in FIG. 4) of accommodation sections 72d from the distal end side of carrier tape 72 are empty accommodation sections 72d1 in which component 91 is not accommodated. When loading carrier tape 72, tape loading mechanism 23 conveys carrier tape 72 by the number of empty accommodation sections 72d1, and positions leading accommodation section 72d accommodating component 91 at a predetermined position with respect to collection position 63.

The predetermined number may vary depending on the type of carrier tape 72. The predetermined number may vary depending on whether carrier tape 72 is unused or in use. In either case, when the number of empty accommodation sections 72d1 is different, tape loading mechanism 23 needs to change the operation condition (such as the feed amount of carrier tape 72) when loading carrier tape 72.

Here, change section 82 changes, based on the component container information, the operation condition of setup device 10 in a case where carrier tape 72 is conveyed by the number of empty accommodation sections 72d1 and leading accommodation section 72d in which component 91 is accommodated is positioned at a predetermined position with respect to collection position 63. The predetermined position can be freely set with respect to collection position 63. For example, when leading accommodation section 72d in which component 91 is accommodated is positioned at collection position 63 or on the downstream side (the second end side (arrow Y2 direction) in the second direction illustrated in FIG. 3) of collection position 63, component 91 is likely to fall off because accommodation section 72d is opened.

Therefore, the predetermined position may be set on the upstream side (the first end side (arrow Y1 direction) in the second direction illustrated in FIG. 3) of collection position 63. For example, the predetermined position can be set on the upstream side (the first end side (arrow Y1 direction) in the second direction) of collection position 63 by one pitch of the pitch interval of accommodation section 72d. For example, in the case of reel 70 on which carrier tape 72 illustrated in FIG. 4 is wound, the number of empty accommodation sections 72d1 is three, and is included in the component container information.

Change section 82 changes the operation condition to an operation condition for conveying carrier tape 72 by three empty accommodation sections 72d1 from the distal end side of carrier tape 72. After it is confirmed that component 91 is accommodated in the fourth accommodation section 72d from the distal end side of carrier tape 72, change section 82 changes the operation condition to the operation condition of winding back carrier tape 72 to the upstream side (the first end side (arrow Y1 direction) in the second direction) of collection position 63 by one pitch of the pitch interval of accommodation section 72d.

Whether accommodation section 72d is empty accommodation section 72d1 can be determined by various methods. Change section 82 can also change the operation conditions of setup device 10 by selecting the determination method. Specifically, setup device 10 can execute multiple determination methods including at least one of a first determination method and a second determination method. Change section 82 changes the operation conditions of setup device 10 by selecting any one of the multiple determination methods.

As illustrated in FIG. 9, in the first determination method, accommodation section 72d from which cover tape 72b is peeled off from base tape 72a is imaged by imaging device 94, and whether accommodation section 72d is empty accommodation section 72d1 is determined based on the image captured by imaging device 94. Imaging device 94 need only be capable of imaging accommodation section 72d and may be various known imaging devices. In the embodiment, camera 23b provided in tape loading mechanism 23 illustrated in FIG. 2 is used as imaging device 94.

When component 91 is not recognized in the image of accommodation section 72d imaged by imaging device 94, setup device 10 determines that accommodation section 72d is empty accommodation section 72d1. Conversely, when component 91 is recognized in the image of accommodation section 72d imaged by imaging device 94, setup device 10 determines that accommodation section 72d is not empty accommodation section 72d1.

When selecting the first determination method, change section 82 can change at least one of an imaging condition when imaging device 94 images the image of accommodation section 72d and an image processing condition when the image captured by imaging device 94 is subjected to the image processing based on the component container information. For example, an exposure time, an aperture value, a type of a light source, and a light irradiation direction of imaging device 94 are included in the imaging conditions. The operation condition of imaging device 94 is changed by change section 82 changing the imaging condition according to at least one of the type of component 91 and the type of carrier tape 72. The image processing conditions include, for example, the presence or absence of pre-processing such as noise removal, the type of image processing such as binarization processing, and a threshold for performing binarization processing. The operation condition of the image processing device is changed by change section 82 changing the image processing condition according to at least one of the type of component 91 and the type of carrier tape 72.

As illustrated in FIG. 9, in the second determination method, a distance from base tape 72a to component 91 accommodated in accommodation section 72d from which cover tape 72b is peeled off is measured using measurement device 95, and it is determined whether accommodation section 72d is empty accommodation section 72d1 based on the distance. Measurement device 95 need only be capable of measuring the distance to component 91 accommodated in accommodation section 72d and may be various known measurement devices. Measurement device 95 may be, for example, a laser measuring instrument that irradiates component 91 with laser light and measures the distance to component 91.

Setup device 10 determines that accommodation section 72d is empty accommodation section 72d1 when the distance measured by measurement device 95 is in a predetermined range assumed when accommodation section 72d is empty accommodation section 72d1. Conversely, when the distance measured by measurement device 95 is shorter than the predetermined range, setup device 10 determines that accommodation section 72d is not empty accommodation section 72d1.

In addition, it is difficult to recognize component 91 only by the first determination method due to a difference in color of component 91, limitation of an imaging condition of imaging device 94, or the like. In addition, as the size of component 91 becomes smaller, the measurement by measurement device 95 becomes more difficult, and it is more difficult to recognize component 91 only by the second determination method. Therefore, setup device 10 can execute the first determination method or the second determination method according to the type of component 91, for example. Setup device 10 can also execute the first determination method, the second determination method, and other determination methods according to the type of component 91. The other determination method is not limited, and a known determination method capable of determining the presence or absence of component 91 can be adopted.

In the embodiment, component supply unit 93 is feeder 60 that conveys carrier tape 72 in a state in which reel 70 is rotatably supported, opens accommodation section 72d closed by cover tape 72b on the upstream side of collection position 63, and supplies component 91 at collection position 63. As illustrated in FIGS. 4 and 5, cover tape 72b is attached to both end portions of base tape 72a in the width direction. Specifically, cover tape 72b is attached to the upper surfaces of both end portions of base tape 72a in the width direction by, for example, adhesive 72f or thermocompression bonding.

Change section 82 can also change the operation conditions of setup device 10 according to an opening method in which feeder 60 opens accommodation section 72d. For example, the opening method includes a first opening method and a second opening method. In the first opening method, cover tape 72b is peeled off from base tape 72a at both end portions of base tape 72a in the width direction to open accommodation section 72d. In the second opening method, accommodation section 72d is opened in a state where cover tape 72b is attached to base tape 72a in a first one of both end portions of base tape 72a in the width direction.

For example, in the embodiment, feeder 60 includes a peeling blade (tape peeling section) that peels off cover tape 72b from base tape 72a. The peeling blade is provided on the upstream side (the first end side (arrow Y1 direction) in the second direction illustrated in FIG. 3) of collection position 63, and enters between base tape 72a and cover tape 72b to peel off cover tape 72b from base tape 72a. In the first opening method, the peeling blade is disposed at a portion where cover tape 72b is attached at both end portions of base tape 72a in the width direction, and peels off cover tape 72b from base tape 72a.

In the second opening method, the peeling blade is disposed at a portion, to which cover tape 72b is attached, of a second one (for example, end portion on the side where feed hole 72e is not provided) of both end portions in the width direction of base tape 72a, and peels off cover tape 72b from base tape 72a. Accordingly, accommodation section 72d is opened in a state where cover tape 72b is attached to base tape 72a in the first one (for example, end portion on the side where feed hole 72e is provided) of both end portions of base tape 72a in the width direction.

In this way, change section 82 can change the operation conditions of setup device 10 by selecting the first opening method or the second opening method. The opening of accommodation section 72d need only be capable of bringing component 91 supplied to collection position 63 in a state of being collectable by the component mounter and is not limited to peeling of cover tape 72b.

### 1-3-3. Collation Section 83

Collation section 83 collates whether component container 92 and component supply unit 93 to be set by setup device 10 are compatible with each other (Step S22 illustrated in FIG. 8). Collation section 83 need only be capable of collating whether component container 92 and component supply unit 93 are compatible with each other and may have various forms.

In the embodiment, component container 92 is reel 70. An identification code for identifying reel 70 is given to each reel 70. In the embodiment, component supply unit 93 is feeder 60. An identification code for identifying feeder 60 is given to each of feeders 60. Setup device 10 includes a code reader capable of reading the identification code. Collation section 83 acquires the identification information of reel 70 read by the code reader and the identification information of feeder 60 read by the code reader.

For example, collation section 83 recognizes the type of reel 70 based on the acquired identification information of reel 70. Collation section 83 recognizes the type of feeder 60 based on the acquired identification information of feeder 60. When the recognized type of reel 70 and the recognized type of feeder 60 are compatible with each other, collation section 83 determines that component container 92 and component supply unit 93 are compatible with each other (Yes in Step S22). Conversely, when the recognized type of reel 70 and the recognized type of feeder 60 are not compatible with each other, collation section 83 determines that component container 92 and component supply unit 93 are not compatible with each other (No in Step S22).

The types of the compatible reel 70 and feeder 60 are confirmed in advance and stored in storage section 81. When component container 92 and component supply unit 93 are compatible with each other (Yes in Step S22), the control by setup system 80 proceeds to control illustrated in Step S23. When component container 92 and component supply unit 93 are not compatible with each other (No in Step S22), the control by setup system 80 temporarily ends. When component container 92 and component supply unit 93 are not compatible with each other, collation section 83 can also inform the worker of this fact.

### 1-3-4. Correction Section 84

When the operation condition of setup device 10 changed by change section 82 is inappropriate, correction section 84 corrects the operation condition of setup device 10 (Steps S25 and S26 illustrated in FIG. 8). In the above case, correction section 84 need only be capable of correcting the operation conditions of setup device 10 and may have various forms.

For example, it is assumed that the number of failures in which component container 92 cannot be appropriately set to component supply unit 93 for component container 92 of a predetermined type exceeds the allowable number of times. In this case, correction section 84 determines that the operation condition of setup device 10 for component container 92 of the predetermined type is inappropriate (Yes in Step S25). Then, correction section 84 corrects the operation condition of setup device 10 (Step S26). For example, correction section 84 can inform the worker to the fact that the operation condition of setup device 10 is inappropriate, and accept the correction of the operation condition by the worker.

When the number of failures is equal to or less than the allowable number of times, correction section 84 determines that the operation condition of setup device 10 for component container 92 of the predetermined type is appropriate (No in Step S25). In this case, the control by setup system 80 temporarily ends. What has been described above about component container 92 also applies to component supply unit 93.

### 2. Other Embodiments

The change of the operation conditions of setup device 10 by change section 82 is not limited to the above description. Change section 82 can change various operation conditions of setup device 10. For example, when the type of feeder 60 is different, a routing path of carrier tape 72 may be different, and the operation condition of finger 23c of tape loading mechanism 23 that grips carrier tape 72 may be different. Change section 82 can change the operation condition of finger 23c of tape loading mechanism 23 according to the type of feeder 60. Further, change section 82 may change the operation condition when reel detachment mechanism 24 detaches reel 70 based on at least one of the component container information and the component supply unit information. Component container 92 may be a tray on which components 91 are arranged. Further, component supply unit 93 may be a tray pallet that is equipped with a tray and supplies component 91 to the collection position.

### 3. Setup Method

The above description of setup system 80 also applies to the setup method. Specifically, in a storage step, at least one of the component container information and the component supply unit information is stored in storage section 81. In a change step, the operation condition for setting component container 92 to component supply unit 93 by setup device 10 is changed based on at least one of the component container information and the component supply unit information stored in storage section 81.

The setup method may include a collation step. In the collation step, whether component container 92 and component supply unit 93 to be set by setup device 10 are compatible with each other is collated. The setup method may include a correction step. In the correction step, the operation condition of setup device 10 is corrected when the operation condition of setup device 10 changed by the change step is inappropriate.

### 4. Example of Advantageous Effects of Embodiment

With setup system 80, the operation condition when setup device 10 sets component container 92 to component supply unit 93 can be changed based on at least one of the component container information and the component supply unit information stored in storage section 81. The above description of setup system 80 can be similarly applied to the setup method.

### REFERENCE SIGNS LIST

10: setup device, 60: feeder, 63: collection position, 70: reel, 72: carrier tape, 72a: base tape, 72b: cover tape, 72d: accommodation section, 72d1: empty accommodation section, 80: setup system, 81: storage section, 82: change section, 83: collation section, 84: correction section, 91: component, 92: component container, 93: component supply unit, 94: imaging device, 95: measurement device

1. A setup system comprising:
a storage section configured to store at least one of component container information that is information related to a component container configured to accommodate a component to be mounted on a board and component supply unit information that is information related to a component supply unit configured to supply the component accommodated in the component container to a collection position;
a setup device configured to set the component container to the component supply unit so that the component is capable of being supplied from the component supply unit; and
a change section configured to change an operation condition when the setup device sets the component container to the component supply unit based on at least one of the component container information and the component supply unit information stored in the storage section.

2. The setup system according to claim 1, wherein the component container information includes information related to a type of the component container, and
the component supply unit information includes information that is information related to a type of the component supply unit.

3. The setup system according to claim 1, wherein the component container information includes component information related to the component accommodated in the component container.

4. The setup system according to claim 1, wherein the change section changes an operation condition to the operation condition that matches the component container and the component supply unit to be set by the setup device.

5. The setup system according to claim 1, wherein the component container is a reel around which a carrier tape in which a cover tape that closes an accommodation section configured to accommodate the component is provided on a base tape provided with the accommodation section is wound, and
the component supply unit is a feeder configured to convey the carrier tape in a state of rotatably supporting the reel, open the accommodation section closed by the cover tape on an upstream side of the collection position, and supply the component at the collection position.

6. The setup system according to claim 5, wherein the change section changes the operation condition of the setup device when the carrier tape is conveyed by the number of empty accommodation sections, which are a predetermined number of accommodation sections from a distal end side of the carrier tape and are accommodation sections in which the component is not accommodated, and a leading accommodation section in which the component is accommodated is positioned at a predetermined position with respect to the collection position, based on the component container information.

7. The setup system according to claim 6, wherein the setup device is capable of executing multiple determination methods including at least one of a first determination method of imaging the accommodation section which the cover tape is peeled off from the base tape using an imaging device and determining whether the accommodation section is the empty accommodation section based on an image captured by the imaging device, and a second determination method of measuring a distance to the component accommodated in the accommodation section which the cover tape is peeled off from the base tape using a measurement device and determining whether the accommodation section is the empty accommodation section based on the distance, and the change section changes the operation condition of the setup device by selecting any one of the multiple determination methods.

8. The setup system according to claim 7, wherein, when the first determination method is selected, the change section changes at least one of an imaging condition under which the imaging device images the accommodation section and an image processing condition under which the image captured by the imaging device is image-processed, based on the component container information.

9. The setup system according to claim 5, wherein the change section changes the operation condition of the setup device according to an opening method in which the feeder opens the accommodation section.

10. The setup system according to claim 9, wherein the cover tape is attached to both end portions of the base tape in a width direction, and
the opening method is a first opening method of opening the accommodation section by peeling off the cover tape from the base tape at both of the end portions of the base tape in the width direction, or a second opening method of opening the accommodation section in a state where the cover tape is attached to the base tape at one of both of the end portions of the base tape in the width direction.

11. The setup system according to claim 1, further comprising a collation section configured to collate whether the component container and the component supply unit to be set by the setup device are compatible with each other.

12. The setup system according to claim 1, further comprising a correction section configured to correct the operation condition of the setup device when the operation condition of the setup device changed by the change section is inappropriate.

13. A setup method comprising:
a storage step of storing, in a storage section, at least one of component container information that is information related to a component container configured to accommodate a component to be mounted on a board and component supply unit information that is information related to a component supply unit configured to supply the component accommodated in the component container to a collection position; and
a change step of changing an operation condition when a setup device configured to set the component container to the component supply unit so that the component is capable of being supplied from the component supply unit sets the component container to the component supply unit, based on at least one of the component container information and the component supply unit information stored in the storage section.
